(19) United States
(12) Patent Application Publication
(10) Pub. No.: US 2005/0139916 A1
(43) Pub. Date: Jun. 30, 2005

(54) High voltage semiconductor device and fabricating method thereof

(75) Inventors: Jum Soo Kim, Icheon (KR); Sung Mun Jung, Yeoju-Gun (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor, Inc., Seoul (KR)

(21) Appl. No.: 11/020,276

(22) Filed: Dec. 27, 2004

(30) Foreign Application Priority Data
Dec. 27, 2003 (KR) 10-2003-0098356

(51) Int. Cl. H01L 29/76; H01L 29/94; H01L 31/062; H01L 31/113

(52) U.S. Cl. 257/346

(57) ABSTRACT

A high voltage semiconductor device and fabricating method thereof, enable a high breakdown voltage to be provided from a surface area without forming a dual spacer layer. The semiconductor device includes a semiconductor substrate having source/drain regions separated from each other by a channel region in-between, a gate insulating layer pattern on the channel region, a gate conductor layer pattern on the gate insulating layer, a sidewall insulating layer provided on a sidewall of the gate conductor layer pattern, a salicide suppress layer pattern covering partial, but not entire, surfaces of the source/drain regions, and covering the sidewall insulating layer, and the gate conductor layer pattern, and a metal salicide layer on remaining portions surfaces of the source/drain regions that are not covered with the salicide suppress layer pattern.

### FIELD OF THE INVENTION

The present invention relates to a high voltage semiconductor device and fabricating method thereof, and more particularly, to a high voltage semiconductor device having a high breakdown voltage and fabricating method thereof.

### DISCUSSION OF THE RELATED ART

Generally, a semiconductor package having low-voltage and high-voltage flash devices integrated therein have a feature that when 12.5V is applied to a predetermined pin, the devices indicate the manufacturer and device type. In doing so, the high voltage flash device should be provided with at least 13V breakdown voltage. In order to provide the at least 13V breakdown voltage, the high voltage flash device employs a DDD (double diffusion drain) junction structure and uses a metal silicide layer. In such a case, a high breakdown voltage can be provided in a vertical direction of the junction structure, but cannot be provided to a surface area thereof. To solve such a problem, a single spacer layer is used for the low voltage flash device and a dual spacer layer is used for the high voltage flash device.

FIG. 1 and FIG. 2 are cross-sectional diagrams of a high voltage semiconductor device according to a related art.

Referring to FIG. 1, gate insulating layer patterns 111 and 121 and gate conductor layer patterns 112 and 122 are stacked on first and second areas I and II of a semiconductor substrate 100 divided into the first area I of a low voltage device area and the second area II of a high voltage device area, respectively.

A sidewall insulating layer 131 is formed to cover the gate conductor patterns 112 and 122. The sidewall insulating layer 131 may include an oxide layer about 60 Å thick and a TEOS layer about 200 Å thick.

A nitride layer 132 about 750 Å thick and a gate spacer insulating layer 133 about 750 Å thick are formed on the sidewall insulating layer 131. The gate spacer insulating layer 133 may be formed of TEOS.

A mask layer pattern 134 exposing the first area I and covering the second area II is formed.

And, the gate spacer insulating layer 133 in the first area I is removed by etching, using the mask layer pattern 134 as an etch mask.

Referring to FIG. 2, a mask layer pattern 135 covering the first area I and exposing the second area II is formed.

An anisotrpic etch is carried out to form a sidewall insulating layer 136 in the second area II using the mask layer pattern 135 as an etch mask.

Thereafter, the mask layer pattern 135 is removed.

However, as recognized by the present inventor, the related art method of forming the dual spacer layer needs to form the mask layer patterns exposing the low and high voltage flash areas for forming the single and dual spacer layers, respectively, whereby the overall fabricating process becomes complicated.

### SUMMARY OF THE INVENTION

Accordingly, the present invention is directed to a high voltage semiconductor device and fabricating method thereof that substantially obviates one or more of the above-described and other problems due to limitations and disadvantages of the related art.

An object of the present invention is to provide a high voltage semiconductor device and fabricating method thereof, by which a high breakdown voltage can be provided from a surface area without forming a dual spacer layer and by which the semiconductor device can be simply fabricated.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a high voltage semiconductor device according to the present invention includes a semiconductor substrate having source/drain regions separated from each other by a channel region therebetween, a gate insulating layer pattern on the channel region, a gate conductor layer pattern on the gate insulating layer, a sidewall insulating layer provided as a sidewall of the gate conductor layer pattern, a salicide suppress layer pattern covering partial surfaces of the source/drain regions, the sidewall insulating layer, and the gate conductor layer pattern, and a metal salicide layer on surfaces of the source/drain regions failing to be covered with the salicide suppress layer pattern.

Preferably, the sidewall insulating layer includes an oxide layer and a nitride layer.

Preferably, the salicide suppress layer pattern includes an oxide layer, an oxynitride layer, and a nitride layer.

Preferably, the salicide suppress layer pattern is in an inclusive range of 200 Å to 1500 Å thick, in one Å increments thick.

Preferably, the metal salicide layer is either a Co-salicide layer or a Ti-salicide layer.

Preferably, the high voltage semiconductor device further includes an insulating interlayer covering the metal salicide layer and the salicide suppress layer pattern and a metal contact penetrating the insulating interlayer to be contacted with a partial surface of the metal salicide layer.

In another aspect of the present invention, a method of fabricating a high voltage semiconductor device includes the steps of forming a gate insulating layer pattern and a gate conductor layer pattern on a channel region of a semiconductor substrate, forming source and drain regions adjacent to both sides of the channel area in the semiconductor substrate, respectively by first ion implantation using the gate conductor layer pattern as a first ion implantation mask, forming a sidewall insulating layer on a sidewall of the gate conductor layer pattern, implanting impurity ions in the source and drain regions by second ion implantation using the sidewall insulating layer and the gate conductor layer pattern as a second ion implantation mask, forming a salicide suppress layer pattern covering portions of the source and drain regions, and forming a metal salicide layer on surfaces of the source and drain regions failing to be covered with the salicide suppress layer pattern.

Preferably, the sidewall insulating layer includes an oxide layer/nitride layer 500-1,300 Å thick.

Preferably, the salicide suppress layer pattern includes an oxide layer/oxynitride layer/nitride layer 200-1,500A thick.

Preferably, the metal salicide layer is formed of either a Co-salicide layer or a Ti-salicide layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 and FIG. 2 are cross-sectional diagrams of a high voltage semiconductor device according to a related art;

FIG. 3 is a layout of a high voltage semiconductor device having a high breakdown voltage according to the present invention;

FIG. 4 is a cross-sectional diagram along a cutting line III-III in FIG. 3; and

FIG. 5 and FIG. 6 are cross-sectional diagrams for explaining a method of fabricating a high voltage semiconductor device having a high breakdown voltage according to the present invention.

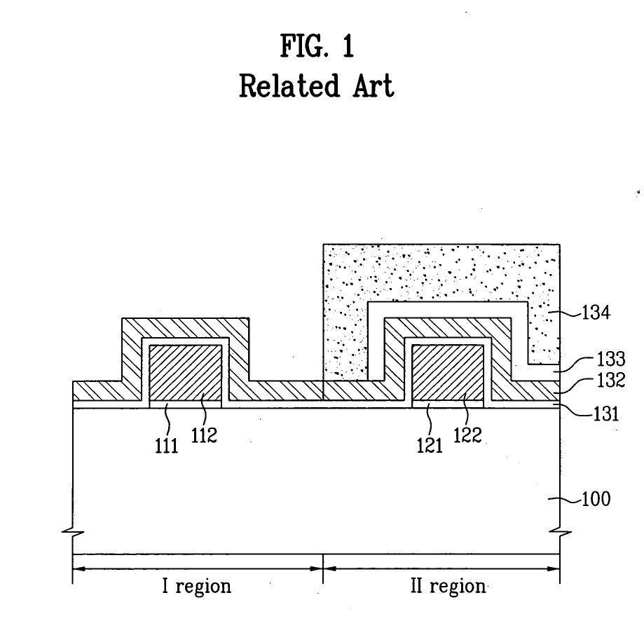

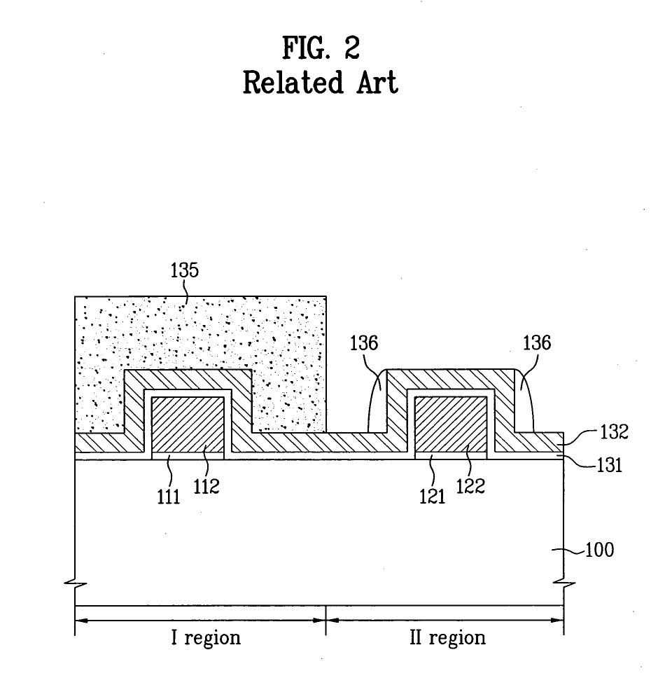

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

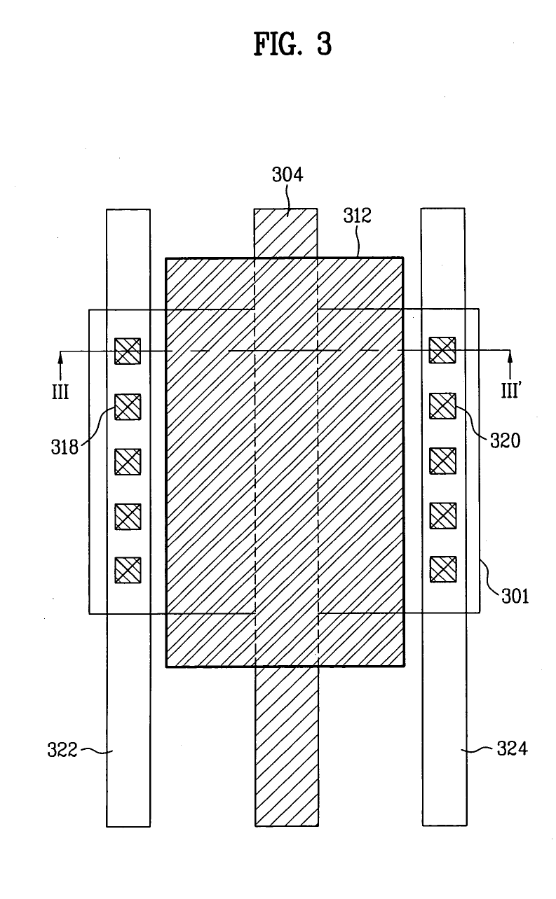

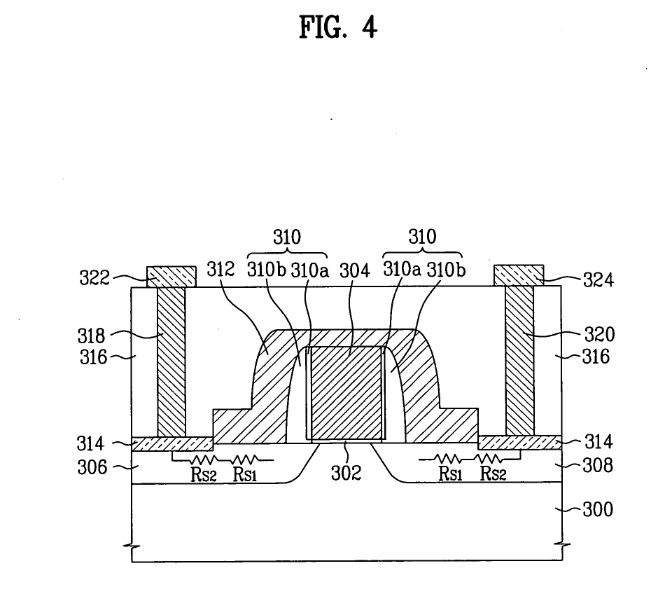

FIG. 3 is a layout of a high voltage semiconductor device having a high breakdown voltage according to the present invention and FIG. 4 is a cross-sectional diagram along a cutting line III-III in FIG. 3.

Referring to FIG. 3 and FIG. 4, a channel region is left between a source region 306 and drain region 308 on a surface of a semiconductor substrate 300. The source and drain regions 306 and 308 employ the DDD (double diffusion drain) junction structure.

A gate insulating layer pattern 302 and a gate conductor layer pattern 304 are sequentially stacked on the channel area. The gate insulating layer pattern 302 is formed of oxide and the gate conductor layer pattern 304 is formed of polysilicon.

A sidewall insulating layer 310 is arranged on a sidewall of the gate conductor layer pattern 304. The sidewall insulating layer 310 includes an oxide layer/nitride layer 310a/310b about 500-1,300 521 thick.

A salicide suppress layer pattern 312 is arranged on partial surfaces of the source and drain regions 306 and 308, the sidewall insulating layer 310, and the gate conductor layer pattern 304. The salicide suppress layer pattern 312 includes an oxide layer/oxynitride layer/nitride layer about 200-1,500 Å thick.

A metal silicide layer 314 is arranged on each surface of the source and drain regions 306 and 308 that is not covered with the salicide suppress layer pattern 312. The metal silicide layer 314 is formed of Co-salicide or Ti-salicide. And, the metal silicide layers 314 are electrically connected to source and drain electrodes 322 and 324 via metal contacts 318 and 320 penetrating an insulating interlayer 316, respectively.

The above-configured high voltage semiconductor device has first and second surface resistances R_{S1} and R_{S2} in a horizontal direction of surfaces of the source and drain regions 306 and 308, respectively. Specifically, the second surface resistance R_{S2} is the resistance caused by the silicide suppress layer pattern 312. A voltage applied from the metal contacts 318 and 320 undergoes a voltage drop caused by the second surface resistance R_{S2}, whereby the same effect of raising a breakdown voltage can take place.

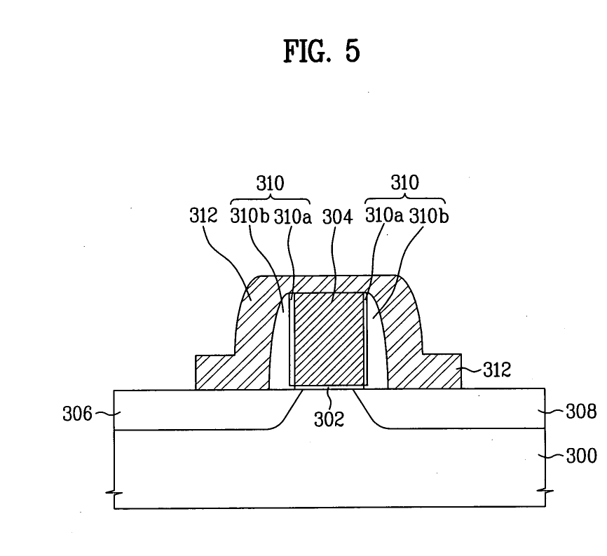

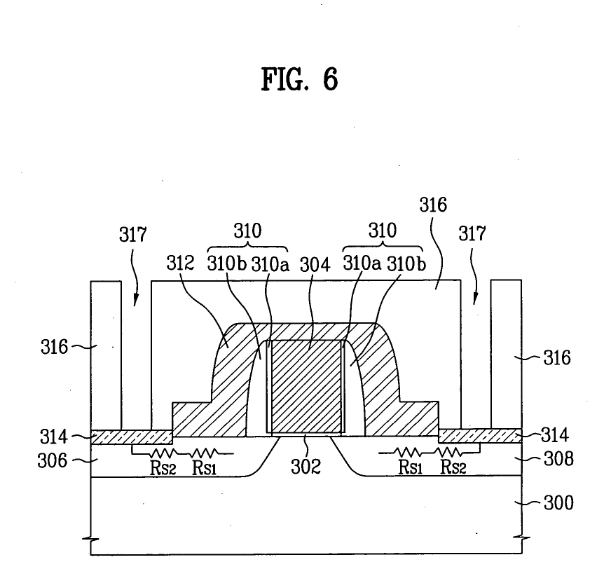

FIG. 5 and FIG. 6 are cross-sectional diagrams for explaining a method of fabricating a high voltage semiconductor device having a high breakdown voltage according to the present invention.

Referring to FIG. 5, a gate insulating layer 302 and a gate conductor layer pattern 304 are formed on a channel region of a semiconductor substrate 300 having an active area defined by a device isolation layer (not shown in the drawing).

Ion implantation is carried out to form a DDD junction structure. In doing so, phosphor (P) is used as a dopant. After completion of the ion implantation, source and drain regions 306 and 308 are formed.

A sidewall insulating layer 310 is formed on a sidewall of the gate conductor layer pattern 304. The sidewall insulating layer 310 is formed of an oxide layer/nitride layer 310a/310b about 500-1,300 Å thick. In forming the sidewall insulating layer 310, the oxide and nitride layers are sequentially formed to cover the gate conductor layer pattern 304 and anisotropic etch is then carried out so that the sidewall insulating layer 310, formed of the oxide layer/nitride layer 310a/310b, is formed on the sidewall of the gate conductor layer pattern 304.

A salicide suppress layer pattern 312 is formed to expose partial surfaces of the source and drain regions 306 and 308. In forming the salicide suppress layer 312, a salicide suppress layer is formed over the substrate. Portions of the salicide suppress layer are then removed to expose the partial surfaces of the source and drain regions 306 and 308 by etching, using a prescribed mask layer pattern (not shown in the drawing). In doing so, a dry etch or a wet etch can be used for the etch. And, the salicide suppress layer pattern 312 includes an oxide layer/oxynitride layer/nitride layer about 200-1,500 Å thick.

Referring to FIG. 6, impurity ions, e.g., phosphor ions are implanted into the source and drain regions 306 and 308 to complete the source and drain regions 306 and 308 of the DDD structure. In implanting the impurity ions, a dose of 5×10¹²-5×10¹⁴ ions/cm³ and ion energy of 40-120 KeV are used.

General metal salicidation is carried out to form a metal salicide layer 312 of each of the exposed surfaces of the source and drain regions 306 and 308. The metal salicide layer 314 can be formed of Co-salicide or Ti-salicide. Specifically, a metal layer, e.g., a Co or Ti layer, is formed over the substrate. Annealing is then performed to form the metal salicide layer 314 on a contact area between the metal layer and each of the source and drain regions 306 and 308. And, the remaining metal layer that fails to react in salicidation is removed.

An insulating interlayer 316 having openings 317 exposing partial surfaces of the metal salicide layer 314 is formed over the substrate.

Metal contacts 318 and 320, as shown in FIG. 4, filing the openings 317 are formed.

Finally, source and drain electrodes 322 and 324 are formed on the metal contacts 318 and 320, respectively.

Accordingly, in the present invention, the voltage applied from the contact can be dropped by forming the salicide suppress layer pattern on the partial surfaces of the source and drain regions without employing the dual spacer layer configuration, whereby the breakdown voltage can be raised.

And, the present invention need not form the dual spacer layer, thereby reducing the number of process steps.

This application claims the benefit of the Korean Application No. P2003-0098356 filed on Dec. 27, 2003, the entire contents of which is hereby incorporated by reference.

It will be apparent to those skilled in the art that various modifications and variations can be made in the present invention. Thus, it is intended that the present invention covers the modifications and variations of this invention provided they come within the scope of the appended claims and their equivalents.

1. A high voltage semiconductor device comprising:
a semiconductor substrate having source/drain regions separated from each other by a channel region therebetween;
a gate insulating layer pattern on the channel region;
a gate conductor layer pattern on the gate insulating layer;
a sidewall insulating layer provided on a sidewall of the gate conductor layer pattern;
a salicide suppress layer pattern covering partial, but not entire, surfaces of the source/drain regions, as well as covering the sidewall insulating layer, and the gate conductor layer pattern; and
a metal salicide layer disposed on remaining surfaces of the source/drain regions that are not covered with the salicide suppress layer pattern.

2. The high voltage semiconductor device of claim 1, wherein the sidewall insulating layer comprises an oxide layer and a nitride layer.

3. The high voltage semiconductor device of claim 1, wherein the salicide suppress layer pattern comprises an oxide layer, an oxynitride layer, and a nitride layer.

4. The high voltage semiconductor device of claim 1, wherein the salicide suppress layer pattern has a thickness in an inclusive range of 200 Å through 1,500 Å.

5. The high voltage semiconductor device of claim 1, wherein the metal salicide layer is at least one of a Co-salicide layer and a Ti-salicide layer.

6. The high voltage semiconductor device of claim 1, further comprising:
an insulating interlayer covering the metal salicide layer and the salicide suppress layer pattern; and
a metal contact penetrating the insulating interlayer and in contact with a portion of the surface of the metal salicide layer.

7. A method of fabricating a high voltage semiconductor device, comprising the steps of:
forming a gate insulating layer pattern and a gate conductor layer pattern on a channel region of a semiconductor substrate;
forming source and drain regions adjacent to both sides of the channel area in the semiconductor substrate respectively by first ion implantation using the gate conductor layer pattern as a first ion implantation mask;
forming a sidewall insulating layer on a sidewall of the gate conductor layer pattern;
implanting impurity ions in the source and drain regions by second ion implantation using the sidewall insulating layer and the gate conductor layer pattern as a second ion implantation mask;
forming a salicide suppress layer pattern covering portions, but not an entirety, of the source and drain regions; and
forming a metal salicide layer on remaining surfaces of the source and drain regions that were not covered in the salicide suppress layer pattern step.

8. The method of claim 7, wherein the step of forming a sidewall insulating layer includes forming an oxide layer/nitride layer having a thickness in an inclusive range of 500 Å through 1300 Å.

9. The method of claim 7, wherein the step of forming salicide suppress layer pattern comprises forming an oxide layer/oxynitride layer/nitride layer having a thickness in an inclusive range of 500 Å through 1300 Å.

10. The method of claim 7, wherein the step of forming a metal salicide layer includes forming one of a Co-salicide layer and a Ti-salicide layer.

11. A method of fabricating a high voltage semiconductor device comprising the steps for:
forming a gate insulating layer pattern and a gate conductor layer pattern on a channel region of a semiconductor substrate;
forming source and drain regions adjacent to both sides of the channel area in the semiconductor substrate respectively by first ion implantation using the gate conductor layer pattern as a first ion implantation mask;
forming a sidewall insulating layer on a sidewall of the gate conductor layer pattern;
implanting impurity ions in the source and drain regions by second ion implantation using the sidewall insulating layer and the gate conductor layer pattern as a second ion implantation mask;
forming a salicide suppress layer pattern covering portions, but not an entirety, of the source and drain regions; and
forming a metal salicide layer on remaining surfaces of the source and drain regions that were not covered in the salicide suppress layer pattern step.
